(19) United States
(12) Patent Application Publication
(10) Pub. No.: US 2023/0253219 A1
(43) Pub. Date: Aug. 10, 2023

(54) SUBSTRATE PROCESSING APPARATUS, SUBSTRATE PROCESSING METHOD, AND STORAGE MEDIUM

(71) Applicant: Tokyo Electron Limited, (US)

(72) Inventors: Yuichiro KUNUGIMOTO, Koshi City (JP); Hideki KAJIWARA, Koshi City (JP); Kazuhiro MATSUURA, Koshi City (JP); Shinichi MIZUSHINO, Koshi City (JP); Hokuto SHIGEMOTO, Koshi City (JP); Akihiro TOYOZAWA, Koshi City (JP); Yuji SAKAI, Koshi City (JP)

(21) Appl. No.: 18/105,993

(22) Filed: Feb. 6, 2023

(30) Foreign Application Priority Data
Feb. 7, 2022 (JP) 2022-016959
Dec. 7, 2022 (JP) 2022-195694

(51) Int. Cl. H01L 21/67; H01L 21/687; H01L 21/68

(52) U.S. Cl. CPC H01L 21/6715; H01L 21/68764; H01L 21/681

(57) ABSTRACT

A substrate processing apparatus includes: a rotary holder configured to hold and rotate a substrate; a cup arranged so as to surround the substrate held by the rotary holder; a coating liquid nozzle configured to inject a coating liquid onto the substrate; a removal liquid nozzle configured to inject, onto the substrate, a removal liquid for removing a film from a peripheral portion of the substrate; a nozzle tracking camera attached to a nozzle arm that holds the coating liquid nozzle so as to track the coating liquid nozzle and configured to capture an image of the coating liquid nozzle; and a processing space camera configured to capture an image of a processing space above the rotary holder.

### CROSS-REFERENCE TO RELATED APPLICATIONS

This application is based upon and claims the benefit of priority from Japanese Patent Application Nos. 2022-016959 and 2022-195694, filed on Feb. 7, 2022 and Dec. 7, 2022, respectively, the entire contents of which are incorporated herein by reference.

### TECHNICAL FIELD

The present disclosure relates to a substrate processing apparatus, a substrate processing method, and a non-transitory computer-readable storage medium.

### BACKGROUND

Patent Document 1 discloses, when substrate lots are switched in an apparatus for coating a coating liquid on the substrate lots, a technique that enables substrate processing to be rapidly performed on subsequent substrate lots.

### PRIOR ART DOCUMENT

### Patent Document

Patent Document 1: Japanese Laid-Open Patent Publication No. 2012-142381

### SUMMARY

A substrate processing apparatus according to an aspect of the present disclosure includes: a rotary holder configured to hold and rotate a substrate; a cup arranged so as to surround the substrate held by the rotary holder; a coating liquid nozzle configured to inject a coating liquid onto the substrate; a removal liquid nozzle configured to inject, onto the substrate, a removal liquid for removing a film from a peripheral portion of the substrate; a nozzle tracking camera attached to a nozzle arm that holds the coating liquid nozzle so as to track the coating liquid nozzle and configured to capture an image of the coating liquid nozzle; and a processing space camera configured to capture an image of a processing space above the rotary holder.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a resist coating apparatus according to an embodiment.

FIG. 2 is a diagram showing a schematic configuration of the resist coating apparatus shown in FIG. 1.

FIG. 3 is a vertical side view of the resist coating apparatus shown in FIG. 1.

FIG. 4 is a vertical side view of the resist coating apparatus shown in FIG. 1.

FIG. 5 is a vertical side view of the resist coating apparatus shown in FIG. 1.

FIG. 6 is a diagram for explaining an operation of capturing an image of a coating liquid nozzle at multiple directions.

FIG. 7 is a diagram showing schematic configurations of a removal liquid nozzle standby bus and a bus camera.

FIG. 8 is a schematic diagram illustrating a hardware configuration of a controller.

FIG. 9 is a diagram illustrating a configuration of a second standby bus according to a modification.

FIG. 10 is a diagram illustrating the configuration of the second standby bus according to the modification.

FIG. 11 is a diagram illustrating the configuration of the second standby bus according to the modification.

FIG. 12 is a perspective view of a cup pullout structure according to a modification.

FIG. 13 is a plan view of a resist coating apparatus according to a modification.

FIG. 14 is a vertical side view of the resist coating apparatus shown in FIG. 13.

FIGS. 15A to 15F are diagrams showing a flow of a cup replacement operation according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

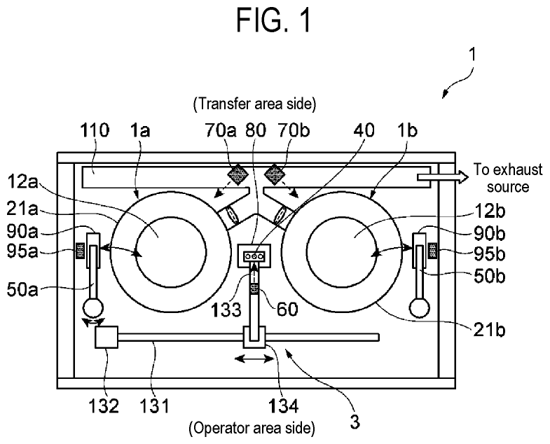

FIG. 1 is a plan view of a resist coating apparatus 1 according to an embodiment. The resist coating apparatus 1 is an apparatus (substrate processing apparatus) included in a substrate processing system for forming a photosensitive film on a substrate, exposing the photosensitive film, and developing the photosensitive film. The substrate to be processed may include a semiconductor wafer, a glass substrate, a mask substrate, an FPD (Flat Panel Display), and the like. The substrate also includes a semiconductor wafer or the like on which a film or the like is formed in a previous process. The resist coating apparatus 1 performs a process of forming a resist film on the surface of the substrate before an exposure process is performed by an exposure apparatus (not shown) included in the substrate processing system. More specifically, the resist coating apparatus 1 supplies a coating liquid for forming a resist film onto the surface of the substrate to form a pre-bake resist film. Further, after forming the pre-bake resist film on the surface of the substrate, the resist coating apparatus 1 removes a peripheral edge portion of the pre-bake resist film by supplying a removal liquid to a peripheral edge portion of the substrate.

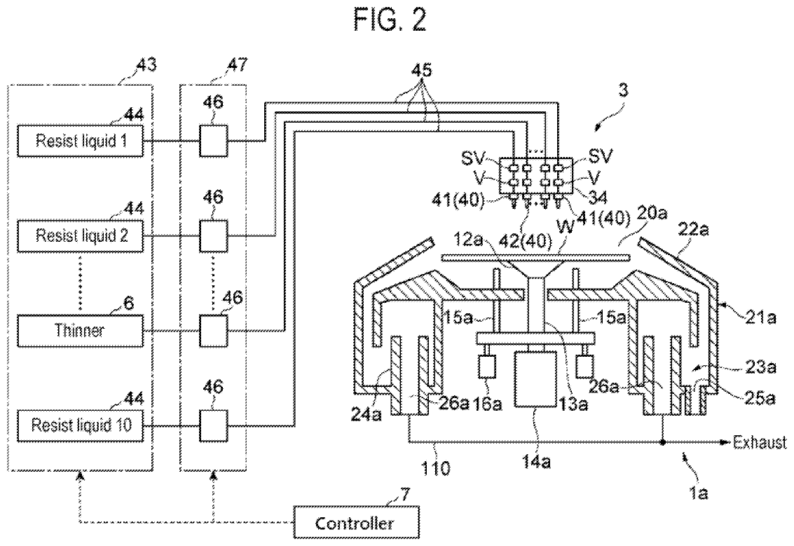

As shown in FIG. 1, the resist coating apparatus 1 includes two coating processing parts 1a and 1b, a nozzle unit 40, a first standby bus 80 (coating liquid nozzle standby bus), and a moving mechanism 3. Further, the resist coating apparatus 1 includes two removal liquid nozzles 50a and 50b, two second standby buses 90a and 90b (removal liquid nozzle standby buses), a nozzle tracking camera 60, and two processing space cameras 70a and 70b. In addition, the resist coating apparatus 1 includes two bus cameras 95a and 95b, an exhaust duct 110, and a controller 7 (see FIG. 2).

The two coating processing parts 1a and 1b are arranged side by side to be adjacent to each other. The coating processing part 1a is configured to include a spin chuck 12a (rotary holder), a cup 21a, and the like. The coating processing part 1b is configured to include a spin chuck 12b (rotary holder), a cup 21b, and the like. Since the coating processing parts 1a and 1b have the same configuration, only the coating processing part 1a will be described below as an example with reference to FIG. 2.

As shown in FIG. 2, the coating processing part 1a includes the spin chuck 12a, which is a rotary holder that attracts a central portion of a back surface of a substrate W to horizontally hold the substrate W and rotates the substrate W. The spin chuck 12a is connected to a rotational drive mechanism 14a via a rotary shaft 13a. The spin chuck 12a is configured to be rotatable about a vertical axis while holding the substrate W through the rotational drive mechanism 14a, and is set so that the center of the substrate W is positioned on the rotation axis thereof. The rotational drive mechanism 14a receives a control signal from the controller 7 to control a rotation speed of the spin chuck 12a.

The cup 21a having an opening 20a on an upper side thereof is provided around the spin chuck 12a so as to surround the substrate W on the spin chuck 12a. An upper end side of a side peripheral surface of the cup 21a forms an inclined portion 22a which is inclined inward. A liquid receiving portion 23a having, for example, a concave shape, is provided on a bottom side of the cup 21a. The liquid receiving portion 23a is divided into an outer region and an inner region over the entire periphery on the lower side of the peripheral edge of the substrate W by a partition wall 24a. A drainage port 25a for discharging an accumulated resist or the like is provided in a bottom of the outer region, and an exhaust port 26a for exhausting a processing atmosphere is provided in a bottom of the inner region.

One end of the exhaust duct 110 is connected to the exhaust port 26a, and the other end of the exhaust duct 110 is connected to a factory exhaust source (see FIG. 1) via an exhaust damper. Thus, the exhaust duct 110 is connected to the exhaust port 26a of the cup 21a and to the exhaust source.

Three lift pins 15a (only two of which are shown in FIG. 2 for the sake of convenience in illustration) are provided in the cup 21a. The lift pins 15a are moved up and down by an elevating mechanism 16a to deliver the substrate W between the substrate transfer mechanism (not shown) for transferring the substrate W to the resist coating apparatus 1 and the spin chuck 12a.

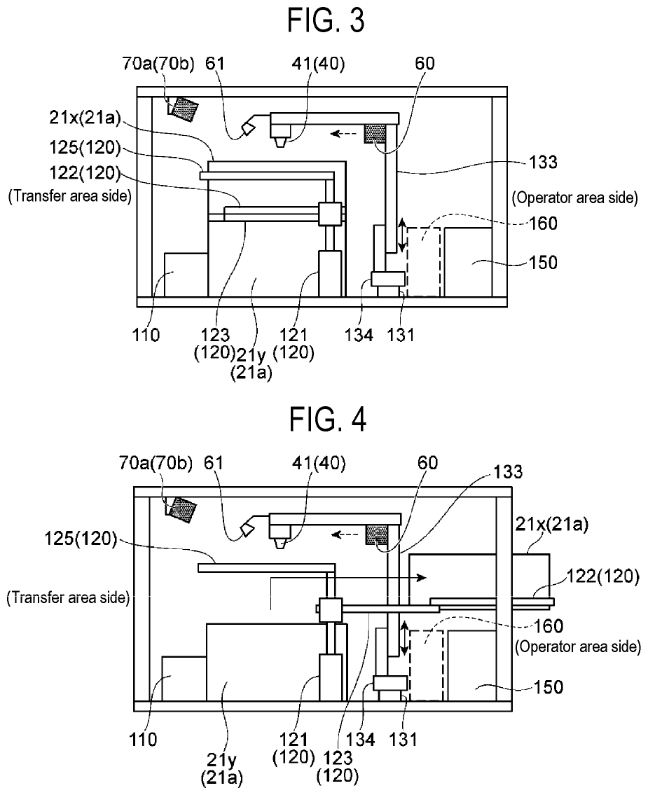

As shown in FIG. 3, specifically, the cup 21a includes a cup base 21y and a movable cup portion 21x. The cup base 21y is a portion that supports the movable cup portion 21x. The movable cup portion 21x is detachably placed on the cup base 21y. The movable cup portion 21x is configured to be pulled out by a cup pullout structure 120.

The cup pullout structure 120 includes a cup elevator 121, a first rail 122 and a second rail 123 which constitute slide rails, and a cup positioner 125. The cup elevator 121 is configured to move up and down to move the slide rails and the cup positioner 125 up and down, thereby raising and lowering the movable cup portion 21x held by the slide rails. The cup positioner 125 is positioned above the movable cup portion 21x held by the slide rails, and is configured to position the movable cup portion 21x. The first rail 122 and the second rail 123 are slide rails that hold the movable cup portion 21x and extend in a predetermined direction (specifically, toward an operator area side) so that the movable cup portion 21x may be pulled out and pushed in. The first rail 122 is configured to directly hold the movable cup portion 21x. The second rail 123 is configured to hold the first rail 122. The cup positioner 125 includes an arc-shaped contact portion that is in contact with the movable cup portion 21x located at a position before being pulled out (normal position) in the outer circumferential direction. A cup fixing mechanism (not shown) that may fix the movable cup portion 21x firmly may be provided on the first rail 122 and the second rail 123. The cup fixing mechanism is, for example, a mechanism for relatively fixing the first rail 122 and the second rail 123, and may be a physical fixing member such as a latch or the like, or an electrically-controlled fixing member using an electromagnet or the like. With this cup fixing mechanism, when the movable cup portion 21x is pushed in, the horizontal and vertical positions of the movable cup are roughly defined by the arc-shaped contact of the cup positioner. Then, after being pushed in, the movable cup portion 21x is finally fixed by using the cup fixing mechanism. In other words, there is less concern about damage due to interference with other members, and the cup may be easily pushed in and installed.

FIG. 4 shows a state in which the movable cup portion 21x is pulled out to the operator area side by extending the first rail 122 and the second rail 123 that constitute the slide rails. The expression “operator area” is an area (front area) on the operator side when viewed from above, and is an area on the opposite side of a transfer area (rear area) in which the substrate W is transferred. As shown in FIG. 4, when pulling out the movable cup portion 21x, first, the cup elevator 121 is moved up from the state in which the movable cup portion 21x is stored, and then the second rail 123 is caused to extend toward the operator area side. Further, by extending the first rail 122 toward the operator area side, the movable cup portion 21x is pulled out toward the operator area side. By extending the first rail 122 and the second rail 123 in two stages in this manner, the movable cup portion 21x may be pulled out to the front side (toward the operator area side), which makes it possible to improve the workability involved in pulling out the movable cup portion 21x.

The nozzle unit 40 is attached to a tip portion of a nozzle arm 133 of the moving mechanism 3, which will be described later. As shown in FIG. 2, the nozzle unit 40 includes a plurality of coating liquid nozzles 41 configured to be capable of injecting a plurality of types (e.g., 10 types) of resist onto the substrate W. Further, the nozzle unit 40 includes a processing liquid nozzle 42 configured to be capable of injecting a processing liquid (e.g., a thinner) that facilitates spreading of the resist on the substrate W. The coating liquid nozzle 41 and the processing liquid nozzle 42 have injection openings opened vertically downward. Chemical liquids injected from the coating liquid nozzle 41 and the processing liquid nozzle 42 are applied to the entire surface of the substrate W by so-called spin coating, in which the chemical liquids spread to the peripheral edge of the substrate W by virtue of a centrifugal force.

As shown in FIG. 2, the coating liquid nozzle 41 and the processing liquid nozzle 42 are supplied with the chemical liquids from a chemical liquid supply unit 43. The chemical liquid supply unit 43 includes a resist supply mechanism 44 that includes a tank in which the chemical liquid to be supplied to the coating liquid nozzle 41 is stored, and a liquid feeding mechanism for pressurizing the interior of the tank to feed the chemical liquid in the tank to the coating liquid nozzle. The resist supply mechanisms 44 are provided in the same number as the coating liquid nozzles 41. Further, the chemical liquid supply unit 43 includes a thinner supply mechanism 6 that includes a tank in which the chemical liquid to be supplied to the processing liquid nozzle 42 is stored, and a liquid feeding mechanism for pressurizing the interior of the tank to feed the chemical liquid in the tank to the processing liquid nozzle 42.

A chemical liquid supply line 45 is provided to connect the coating liquid nozzle 41 and the resist supply mechanism 44 and to connect the processing liquid nozzle 42 and the thinner supply mechanism 6. A flow rate controller 47 including a valve 46 is provided in the chemical liquid supply line 45. Each valve 46 is controlled to be opened and closed according to a control signal supplied from the controller 7, whereby various types of resist and thinner are switched and supplied to the substrate W.

An injection valve V and a suck-back valve SV are provided in series in the named order from the injection side in the nozzle head 34 on a primary side of the coating liquid nozzle 41 and the processing liquid nozzle 42. The injection valve V and the suck-back valve SV are operated by, for example, an air pressure as power. The injection valve V opens and closes a flow path between each chemical liquid supply line 45 and each coating liquid nozzle 41 and the processing liquid nozzle 42 by the air pressure. The suck-back valve SV may adjust a volume and a liquid chemical pressure by a piston mechanism operated by the air pressure.

As shown in FIG. 3, on the operator area side from the nozzle arm 133, a pipe laying cableveyor area 160 for the coating liquid nozzle 41 and an accessory mounting area 150 are provided. Supply system valves and small electrical components are arranged in the accessory mounting area 150.

The exhaust duct 110 requires a certain degree of cross-sectional area in consideration of exhaust performance, especially when exhaust is performed by sharing a single exhaust source by a plurality of processing spaces. When the exhaust duct 110 is arranged horizontally on the same side of the cup as the moving mechanism 3, there is a problem that the stroke of the cup pullout structure 120 required for pulling out the cup is extended, resulting in an increase in the size of the mechanism itself and requiring a strength improvement design. When the exhaust duct 110 is arranged vertically in line with the nozzle movement mechanism or the accessory mounting area 150, the workability of pulling out the cup may be impaired due to the interference with or approach to the path required for pulling out the cup. This is a problem that should be avoided as much as possible in order to carry out necessary works in a substrate processing apparatus, the interior of which is compact and difficult to be directly maintained through manual work. In other words, in the substrate processing apparatus of the present embodiment, the above problem may be solved by arranging the exhaust duct 110 on the opposite side of the cup 21a from the moving mechanism 3.

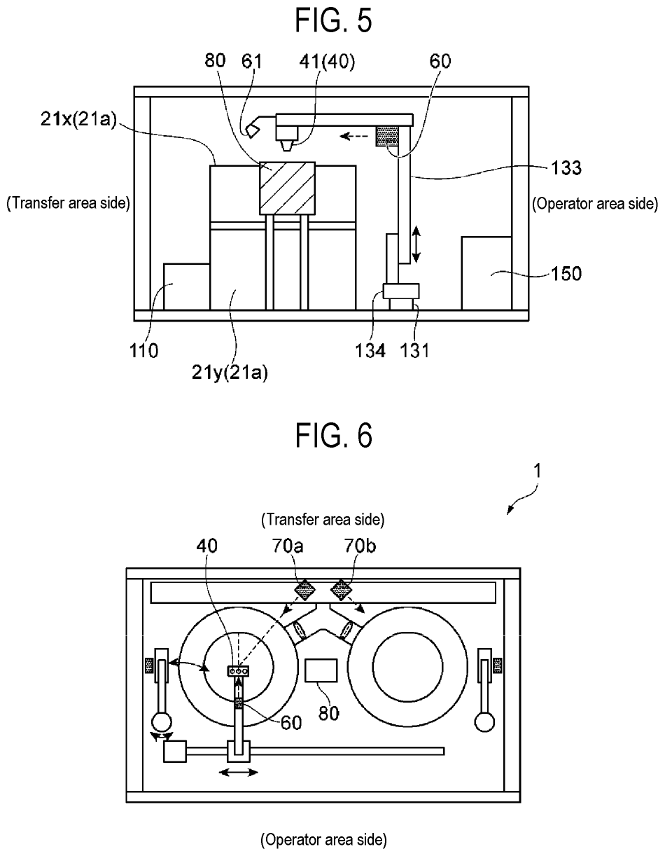

The first standby bus 80 is a standby bus provided in a standby section of the nozzle unit 40 including the coating liquid nozzle 41, as shown in FIGS. 1 and 5. The first standby bus 80 is provided, for example, in an area between the two coating processing parts 1a and 1b (see FIG. 1). As shown in FIG. 5, a height of an upper surface of the first standby bus 80 is substantially equal to or slightly larger than a height of an upper surface of the movable cup portion 21x in the stored state. In addition, the height of the upper surface of the first standby bus 80 is made lower than a height of a moving path of the nozzle unit 40 between the two cups 21a and 21b. As a result, an elevating stroke of the nozzle unit 40 may be shortened, and a space in the height direction of the resist coating apparatus 1 may be reduced.

The moving mechanism 3 is configured to hold and move the nozzle unit 40. As shown in FIG. 1, the moving mechanism 3 includes a nozzle moving shaft 131, a nozzle driving part 132, a nozzle arm 133, and a horizontal moving part 134.

The nozzle arm 133 is a holding member that holds the nozzle unit 40 including the coating liquid nozzle 41. The nozzle arm 133 holds the nozzle unit 40 at its tip. As shown in FIG. 3 and the like, the nozzle arm 133 may be moved up and down by a cylinder, a motor or the like. The horizontal moving part 134 is provided at a base end of the nozzle arm 133 and configured to be horizontally movable along the nozzle moving shaft 131. The nozzle moving shaft 131 extends along the arrangement direction of the two coating processing parts 1a and 1b on the operator area side. The nozzle moving shaft 131 guides the movement of the nozzle arm 133 extending from the horizontal moving part 134 by guiding the horizontal movement of the horizontal moving part 134. The nozzle driving part 132 is, for example, a motor or the like, and configured to move the horizontal moving part 134 along the nozzle moving shaft 131. The nozzle driving part 132 controls the movement of the horizontal moving part 134 according to a control signal from the controller 7.

While the nozzle moving shaft 131 is arranged on the operator area side as described above, the exhaust duct 110 is arranged on the transfer area side opposite to the operator area, as shown in FIG. 1. That is, the exhaust duct 110 and the nozzle moving shaft 131 are arranged separately on the transfer area side and the operator area side. Thus, it is possible to reduce a space in the height direction of the resist coating apparatus 1. The positional relationship between the exhaust duct 110 and the nozzle moving shaft 131 may be opposite to each other. That is, the exhaust duct 110 may be arranged on one of the operator area side and the transfer area side, and the nozzle moving shaft 131 may be arranged on the other of the operator area side and the transfer area side. Further, the exhaust duct 110 is not limited to the configuration shown in FIG. 1. For example, a duct branch portion (not shown) branching from a position facing the center of each of the cups 21a and 21b on the transfer area side and extending toward each of the cups 21a and 21b may be connected to the exhaust port 26a of each of the cups 21a and 21b. Further, a plurality of exhaust ports 26a may be provided in one cup, and branch portions further branching from the duct branching portion in conformity with the number of the exhaust ports 26a may be connected to the plurality of exhaust ports 26a, respectively.

As shown in FIG. 1, the nozzle tracking camera 60 is attached to the nozzle arm 133 so as to track the nozzle unit 40 including the coating liquid nozzle 41, and is configured to capture images of the coating liquid nozzle 41 and the processing liquid nozzle 42. Further, a light 61 for the nozzle tracking camera 60 is provided at the tip of the nozzle arm 133 (see FIG. 3). The nozzle tracking camera 60 is configured to acquire information on positions of the coating liquid nozzle 41 and the processing liquid nozzle 42 with respect to the first standby bus 80, and is configured to acquire information on the liquid behavior in the coating liquid nozzle 41 and the processing liquid nozzle 42. The nozzle tracking camera 60 may include a liquid lens capable of focusing on both the coating liquid nozzle 41 and the processing liquid nozzle 42 that move integrally as the nozzle unit 40.

As shown in FIG. 1, the processing space camera 70a is a camera that is provided on the transfer area side and configured to capture an image of the processing space above the spin chuck 12a. As shown in FIG. 1, the processing space camera 70b is a camera that is provided on the transfer area side and configured to capture an image of the processing space above the spin chuck 12b.

In the resist coating apparatus 1 according to the present embodiment, when adjusting the centering of the nozzles such as the coating liquid nozzle 41 and the like, the information acquired by the nozzle tracking camera 60 and the information acquired by the processing space camera 70a (or the processing space camera 70b) are used. In the example shown in FIG. 6, the nozzle tracking camera 60 is configured to capture an image of the nozzle unit 40 including the coating liquid nozzle 41 as information on the centering of the coating liquid nozzle 41 with respect to the spin chuck 12a. Further, the processing space camera 70a is configured to capture an image of the nozzle unit 40 including the coating liquid nozzle 41 at an angle different from that of the nozzle tracking camera 60 as information on the centering of the coating liquid nozzle 41 with respect to the spin chuck 12a. A difference in capturing angle in this case may be, for example, about 90 degrees. By allowing the nozzle tracking camera 60 and the processing space camera 70a to capture the images of the coating liquid nozzle 41 at different angles in this manner, it is possible to three-dimensionally adjust the centering of the coating liquid nozzle 41 with high accuracy. The processing space cameras 70a and 70b are provided at positions deviated from a straight line connecting the coating liquid nozzle 41, which is a nozzle to be captured, and the light 61 when viewed from above. Further, as shown in FIGS. 1 and 3, the processing space cameras 70a and 70b, which are provided in the resist coating apparatus 1 so as to correspond to the adjacent coating processing parts 1a and 1b, respectively, are arranged above the nozzle tracking camera 60. The processing space cameras 70a and 70b are provided at positions laterally deviated from the cups 21a and 21b (positions outside the cups). Each of the processing space cameras 70a and 70b performs the capturing at an obliquely downward field of view of the substrate present in the corresponding coating processing part from the above positions. Since each of the processing space cameras 70a and 70b is located at a position above the nozzle tracking camera 60 and outside the corresponding cup 21a or 21b, it may be easily arranged in a narrow space while reducing the risk of liquid splashing due to processing or liquid adhesion due to condensation of volatilized liquid. Further, the resist coating apparatus 1 may be made compact. Moreover, in the processing space cameras 70a and 70b, the capturing field of view with respect to the coating liquid nozzle 41 when positioned above the substrate is different from that of the nozzle tracking camera 60 in the vertical plane (e.g., the plane viewed in FIG. 3). For this reason, it becomes easier to capture changes in the three-dimensional position and posture of the coating liquid nozzle 41 than in the case where images are captured substantially horizontally by both cameras. That is, the centering adjustment may be performed with high accuracy.

The nozzle centering adjustment described above is realized by a substrate processing method including the following first to third operations. In the first operation, the nozzle tracking camera 60 captures the image of the coating liquid nozzle 41 from a first direction. In the second operation, the processing space camera 70a (or the processing space camera 70b) captures the image of the coating liquid nozzle 41 from a second direction different from the first direction. In the third operation, the adjustment of centering of the coating liquid nozzle 41 is performed based on the capturing result of the nozzle tracking camera 60 and the capturing result of the processing space camera 70a (or the processing space camera 70b). The third operation may be automatically performed by the controller 7 outputting a control signal.

The removal liquid nozzles 50a and 50b are nozzles configured to inject a removal liquid for removing a film on the peripheral portion of the substrate W to the substrate W, as shown in FIG. 1. The removal liquid nozzle 50a is provided to correspond to the coating processing part 1a. The removal liquid nozzle 50b is provided to correspond to the coating processing part 1b.

As shown in FIG. 1, the second standby bus 90a is a removal liquid nozzle standby bus provided in the standby section of the removal liquid nozzle 50a. The second standby bus 90b is a removal liquid nozzle standby bus provided in the standby section of the removal liquid nozzle 50b. The movement between the standby section of the removal liquid nozzle 50a and the position where the removal liquid is injected onto the substrate W is not limited to a turning movement as indicated by an arrow in FIG. 1. For example, a removal liquid nozzle moving mechanism for linearly moving the removal liquid nozzle 50a may be provided. In addition, the removal liquid nozzle moving mechanism may move up and down.

As shown in FIG. 1, the bus camera 95a is a camera configured to capture an image of the removal liquid nozzle 50a positioned on the second standby bus 90a. The bus camera 95b is a camera configured to capture an image of the removal liquid nozzle 50b positioned on the second standby bus 90b.

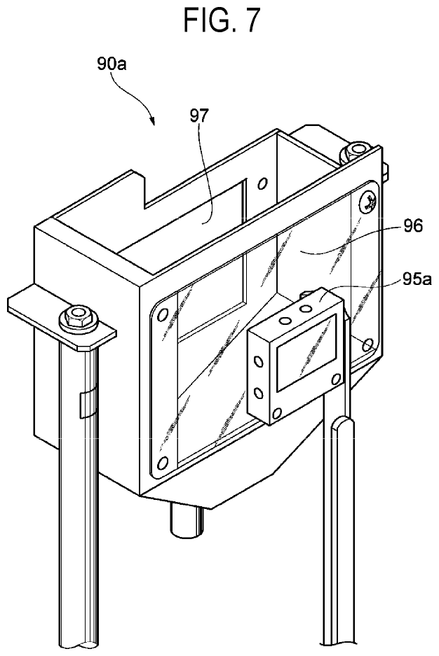

The second standby bus 90a and the bus camera 95a will be described with reference to FIG. 7. Although FIG. 7 shows only the second standby bus 90a and the bus camera 95a, the second standby bus 90b is similar to the second standby bus 90a, and the bus camera 95b is similar to the bus camera 95a.

As shown in FIG. 7, the second standby bus 90a is formed in a substantially rectangular parallelepiped shape. An upper surface portion of the second standby bus 90a forms an opening through which the removal liquid nozzle 50a may be taken in and out. A window 97 for lighting is provided on a surface of the second standby bus 90a facing the cup 21a. The bus camera 95a is provided on a surface facing the window 97 of the second standby bus 90a. That is, the bus camera 95a is provided in a region of the second standby bus 90a that does not face the cup 21a. A window 96 for the camera is provided on a surface on which the bus camera 95a is provided. In addition, the bus camera 95a may be provided with a liquid-receiving and anti-reflection cover.

Regions other than the windows 96 and 97 of the second standby bus 90a may be formed as black surfaces. Further, the second standby bus 90a may be entirely or partially formed with a mirror surface.

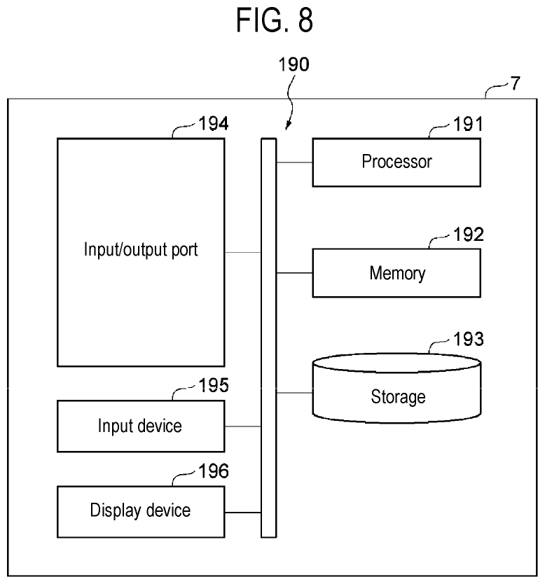

The controller 7 controls each component of the resist coating apparatus 1. The controller 7 is constituted with one or more control computers. As shown in FIG. 8, the controller 7 includes a circuit 190. The circuit 190 includes at least one processor 191, a memory 192, a storage 193, an input/output port 194, an input device 195, and a display device 196.

The storage 193 includes a non-transitory computer-readable storage medium such as a hard disk or the like. The storage 193 stores a program for causing the controller 7 to execute an information processing method of a substrate processing apparatus.

The memory 192 temporarily stores the program loaded from the storage medium of the storage 193 and calculation results obtained by the processor 191. The processor 191 cooperates with the memory 192 to execute the above program, thereby forming each of the above-described functional modules. The input/output port 194 performs input and output of electrical signals between respective components in accordance with instructions from the processor 191.

The input device 195 and the display device 196 function as user interfaces for the controller 7. The input device 195 is, for example, a keyboard or the like, and is configured to acquire information input by the user. The display device 196 includes, for example, a liquid crystal monitor and the like, and is used to display information to the user. The input device 195 and the display device 196 may be integrated as a so-called touch panel.

Next, effects of the resist coating apparatus 1 according to the present embodiment will be described.

The resist coating apparatus 1 according to the present embodiment includes the spin chuck 12a for holding and rotating the substrate W, the cup 21a arranged so as to surround the substrate W held by the spin chuck 12a, and the coating liquid nozzle 41 configured to be capable of injecting the coating liquid onto the substrate W. Further, the resist coating apparatus 1 includes the removal liquid nozzle 50a, and the nozzle tracking camera 60 attached to the nozzle arm 133 that holds the coating liquid nozzle 41 so as to track the coating liquid nozzle 41 and configured to capture the image of the coating liquid nozzle 41. In addition, the resist coating apparatus 1 includes the processing space camera configured to capture the image of the processing space above the spin chuck 12a.

The resist coating apparatus 1 according to the present embodiment is provided with the nozzle tracking camera 60 configured to capture the image of the coating liquid nozzle 41 and the processing space camera 70a configured to capture the image of the processing space above the spin chuck 12a. With such a configuration, it is possible to suitably monitor the operation of the coating liquid nozzle 41 and the operation in the processing space. Various hardware adjustments and maintenance may be suitably carried out based on such operation monitoring results. As described above, with the resist coating apparatus 1 according to the present embodiment, it is possible to improve the usability of the coating process.

The resist coating apparatus 1 further includes the exhaust duct 110 connected to the exhaust port 26a of the cup 21a and connected to the exhaust source, and the nozzle moving shaft 131 for guiding the movement of the nozzle arm 133 that holds the coating liquid nozzle 41. The exhaust duct 110 is arranged on the transfer area side, and the nozzle moving shaft 131 is arranged on the operator area side. By arranging the exhaust duct 110 and the nozzle moving shaft 131 separately on the transfer area side and the operator area side in this way, it is possible to reduce the height of the resist coating apparatus 1. By reducing the thickness of the resist coating apparatus 1, it becomes possible to mount a large number of apparatuses, and it is possible to implement high transaction processing.

The resist coating apparatus 1 includes the first rail 122 that holds the movable cup portion 21x, and the second rail 123 that holds the first rail 122. In the resist coating apparatus 1, the movable cup portion 21x is pulled out by extending the second rail 123 in a predetermined direction and further extending the first rail 122 in the predetermined direction. By extending the first rail 122 and the second rail 123 in two stages in this manner, the movable cup portion 21x may be further pulled out toward the front side, which makes it possible to improve the workability when pulling out the movable cup portion 21x.

The resist coating apparatus 1 further includes the first standby bus 80 provided in the standby section for the coating liquid nozzle 41. The nozzle tracking camera 60 is configured to acquire information on the position of the coating liquid nozzle 41 with respect to the first standby bus 80, and is configured to acquire information on the liquid behavior in the coating liquid nozzle 41. With such a configuration, the nozzle tracking camera 60 recognizes the position of the coating liquid nozzle 41 on the first standby bus 80 and also recognizes the liquid behavior in the coating liquid nozzle 41. In this manner, the nozzle tracking camera 60 monitors not only the position of the coating liquid nozzle 41 but also the liquid behavior in the coating liquid nozzle 41, whereby the operation of the coating liquid nozzle 41 may be monitored more appropriately.

The resist coating apparatus 1 further includes the second standby bus 90a provided in the standby section for the removal liquid nozzle 50a, and the bus camera 95a configured to capture the image of the removal liquid nozzle 50a positioned on the second standby bus 90a. The bus camera 95a is provided in a region of the second standby bus 90a that does not face the cup 21a. With such a configuration, the operation of the removal liquid nozzle 50a on the second standby bus 90a may be appropriately monitored by the bus camera 95a. Since the bus camera 95a is provided in the region that does not face the cup 21a, the bus camera 95a may appropriately capture the image of the removal liquid nozzle 50a while suppressing the influence of the liquid splashing from the cup 21a.

The second standby bus 90a may be entirety or partially formed with the mirror surface. With this configuration, it is possible to reflect light and improve the capturing capability of the bus camera 95a.

Regions other than the windows 96 and 97 of the second standby bus 90a may be formed as black surfaces. With such a configuration, the reflection of unnecessary light may be suppressed, which makes it possible to improve the capturing capability of the bus camera 95a.

The nozzle tracking camera 60 is configured to be able to capture the image of the coating liquid nozzle 41 as information relating to the centering of the coating liquid nozzle 41 with respect to the spin chuck 12a. The processing space camera 70 a is configured to be able to capture the image of the coating liquid nozzle 41 at an angle different from that of the nozzle tracking camera 60 as information relating to the centering of the coating liquid nozzle 41. With such a configuration, the image of the coating liquid nozzle 41 may be captured at different angles, which makes it possible to implement the three-dimensional centering of the coating liquid nozzle 41.

The resist coating apparatus 1 further includes the processing liquid nozzle 42 attached to the nozzle arm 133 together with the coating liquid nozzle 41 and configured to inject the processing liquid that facilitates spreading of the coating liquid on the substrate W. The nozzle tracking camera 60 may have a liquid lens capable of focusing on both the coating liquid nozzle 41 and the processing liquid nozzle 42 that move integrally with each other. By using the nozzle tracking camera 60 having the liquid lens capable of focusing on both the coating liquid nozzle 41 and the processing liquid nozzle 42 that move integrally with each other, it is possible to monitor the operations of the coating liquid nozzle 41 and the processing liquid nozzle 42 more appropriately.

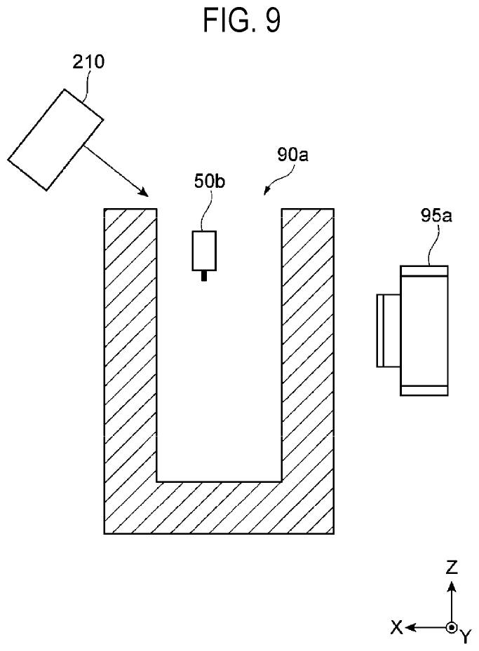

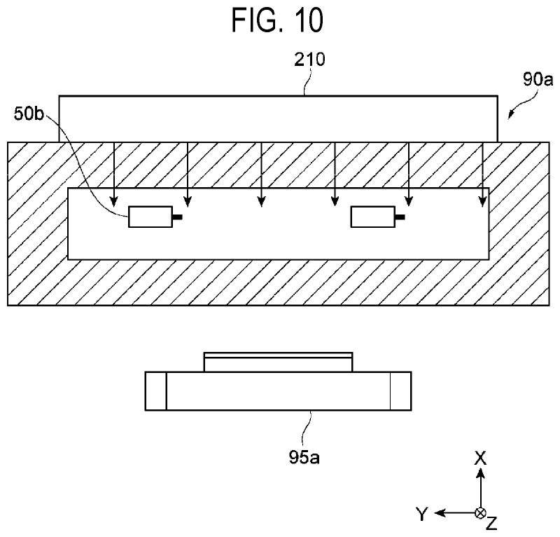

The present disclosure is not limited to the above-described embodiments. For example, although the second standby bus 90a has been described as a removal liquid nozzle standby bus, the configuration of the second standby bus 90a is not limited to the above-described embodiments. FIGS. 9 to 11 are diagrams for explaining the configuration of a second standby bus 90a according to a modification. In FIGS. 9 to 11, three mutually intersecting directions, that is, an X direction, a Y direction, and a Z direction, are shown. The X direction is a direction in which two coating processing parts are adjacent to each other when viewed from above, the Y direction is a direction crossing the X direction when viewed from above, and the Z direction is a vertical direction (height direction). FIG. 9 is a diagram schematically showing an XZ cross-section of the second standby bus 90a, FIG. 10 is a diagram schematically showing an XY cross-section of the second standby bus 90a, and FIG. 11 is a diagram schematically showing an YZ cross-section of the second standby bus 90a.

In configurations shown in FIGS. 9 to 11, an illuminator 210 is further provided as a configuration related to the second standby bus 90a. The illuminator 210 is an illuminator that emits light toward the removal liquid nozzle 50b positioned on the second standby bus 90a.

The illuminator 210 may be configured to include, for example, an LED (Light Emitting Diode) illuminator. The illuminator 210 is provided on the opposite side of the bus camera 95a so as to sandwich the second standby bus 90a between the illuminator 210 and the bus camera 95a. Since the illuminator 210 and the bus camera 95a are arranged in such a manner, the illuminator 210 is provided above the second standby bus 90a to irradiate the removal liquid nozzle 50b with light from above. As shown in FIGS. 10 and 11, the illuminator 210 is provided along the Y direction, which is a longitudinal direction of the second standby bus 90a. The illuminator 210 is provided over substantially the entire area (substantially the entire area in the Y direction) of the upper opening of the second standby bus 90a. Accordingly, the light emitted from the illuminator 210 may clearly check the entire interior region of the second standby bus 90a. With such a configuration, it is possible to appropriately cope with the configuration of multiple nozzle systems as shown in FIGS. 10 and 11.

In addition, in the second standby bus 90a, at least a surface facing the bus camera 95a may be a surface subjected to black surface processing. Further, a surface roughness of each surface of the second standby bus 90a may be mirror-finished. As a result, an object to be visually recognized may be clearly checked with high contrast in the second standby bus 90a. Further, the bus camera 95a may be arranged so as to be able to capture images from a direction intersecting the injection direction of the removal liquid nozzle 50b. That is, as shown in FIG. 9, for example, the bus camera 95a may be arranged so that the liquid column injected in the Z direction from the removal liquid nozzle 50b may be monitored from the X direction side crossing the Z direction.

Further, the cup pullout structure is not limited to the configuration of the cup pullout structure 120 described above, and may be, for example, a cup pullout structure 420 according to a modification shown in FIG. 12. FIG. 12 is a perspective view of the cup pullout structure 420 according to the modification. The cup pullout structure 420 includes a cup elevator 421, a first rail 422 and a second rail 423 that constitute slide rails, a cup placement portion 430, a liquid receiving portion 440, and a stopper 450. The cup pullout structure 420 further includes a pullout lock magnet 460, a storage lock magnet 470, and a cup retainer 480.

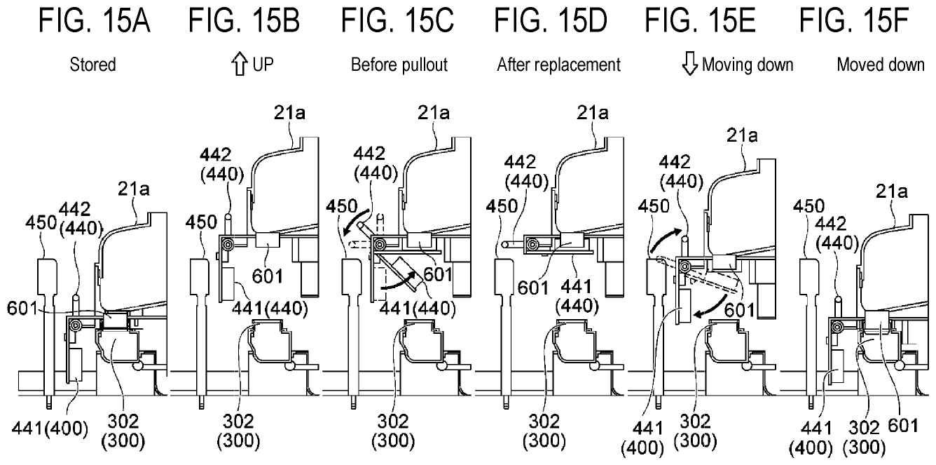

The cup elevator 421, the first rail 422, and the second rail 423 are similar in configuration to the cup elevator 121, the first rail 122, and the second rail 123 of the cup pullout structure 120 described above, respectively. A pullout amount by which the cup 21a is pulled out by the first rail 422 and the second rail 423 may be, for example, about 450 mm. The cup placement portion 430 is a portion extending so as to span between a pair of first rails 422, and is a portion on which a portion of the movable cup portion 21x is placed. A through-hole 430x is formed through the cup placement portion 430 at the central portion of the cup placement portion 430 in a width direction. A cup-side drainpipe 601 (see FIG. 15B and the like) of the cup 21a is inserted into the through-hole 430x. The cup-side drainpipe 601 (see FIG. 15B and the like) is a pipe connected to the drainage port 25a (see FIG. 2) of the cup 21a and extends downward from a lower end of the cup 21a.

The liquid receiving portion 440 is provided at the width-direction central portion of the cup placement portion 430 and is a drain pan that covers the cup-side drainpipe 601. The stopper 450 is configured to displace the liquid receiving portion 440 by coming into contact with the liquid receiving portion 440. Details of the liquid receiving portion 440 and the stopper 450 will be described later with reference to FIGS. 15A to 15F.

The pullout lock magnet 460 is provided at a front end (end portion on the operator area side) of the cup placement portion 430, and is configured to, when pulling out the cup 21a, attract and lock the cup 21a so that the cup 21a may be easily placed on the cup placement portion 430. The storage lock magnet 470 is provided in the vicinity of the cup elevator 421, and is configured to, when storing the cup 21a, attract and lock the cup 21a. The cup retainer 480 is provided above the cup elevator 421, and is configured to retain the cup 21a from above to position the cup 21a. The cup pullout structure 420 may also include an elevation sensor for detecting an elevation state of the cup 21a elevated by the cup elevator 121, a pullout sensor for detecting a pulling-out state of the cup 21a pulled out by the first rail 422 and the second rail 423, and the like.

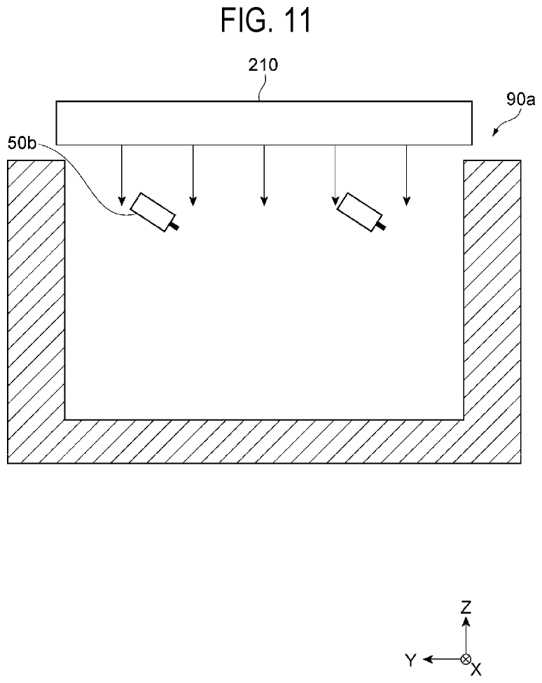

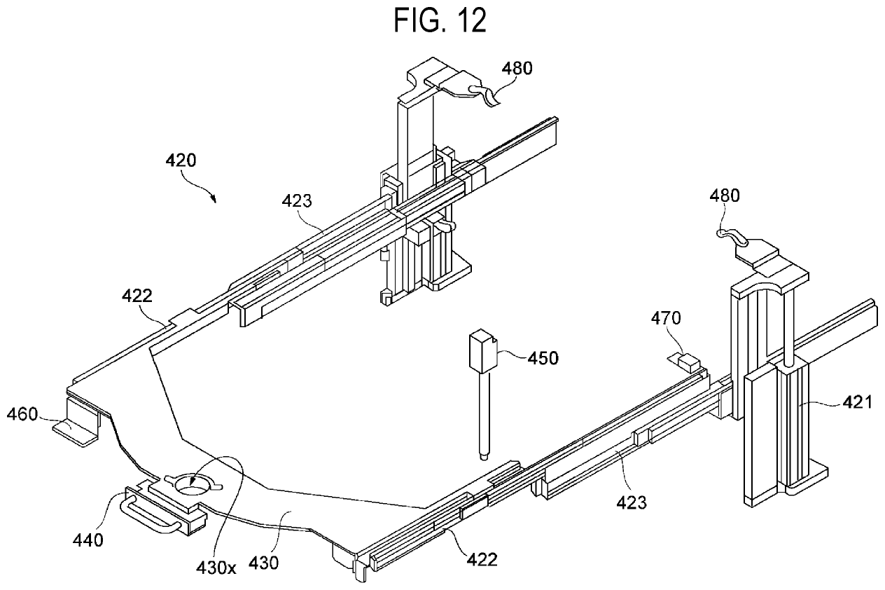

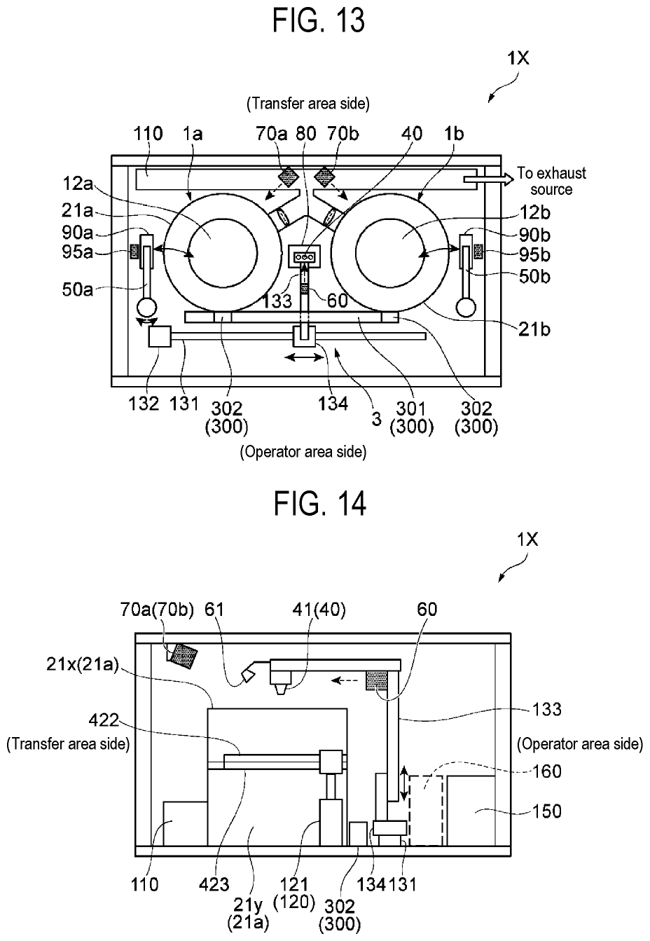

For example, the configuration including the cup pullout structure 420 described above may further include a drainpipe 300 as shown in FIGS. 13 and 14. FIG. 13 is a plan view of a resist coating apparatus 1X according to a modification. FIG. 14 is a vertical side view of the resist coating apparatus 1X shown in FIG. 13. The drainpipe 300 is a pipe connected to the cup-side drain-pipe 601 (see FIG. 15B and the like) (that is, the drainage port 25a of the cup 21a (see FIG. 2)). The drainpipe 300 includes connection pipes 302 and 302 corresponding to the two coating processing parts 1a and 1b, which are connected to the cup-side drainpipe 601 (see FIG. 15B and the like), and a pipe 301 connecting the connection pipes 302 and 302.

As shown in FIG. 14, the drainpipe 300 has a smaller vertical cross-sectional area and a lower height than the exhaust duct 110. Further, as shown in FIG. 13, when viewed from above, the drainpipe 300 is arranged on the opposite side (the other side) of the operator area or the transfer area on whichever the exhaust duct 110 is arranged. In the example shown in FIG. 13, the exhaust duct 110 is provided on the transfer area side, and the drainpipe 300 is provided on the operator area side. By reducing the height of the drainpipe 300 in this way, the drainpipe 300 and the exhaust duct 110 may be arranged separately in the operator area and the transfer area as described above. As a result, for example, as compared with the configuration in which the drainpipe 300 is arranged over the exhaust duct 110 in the same area, it is possible to implement a configuration having a small size in the height direction.

FIGS. 15A to 15F are diagrams showing a flow of a cup replacement operation in the cup pullout structure 420 and the drainpipe 300 according to the modification described above. As shown in FIG. 15A and the like, the liquid receiving portion 440 of the cup pullout structure 420 has a lid portion 441 and a handle portion 442. The lid portion 441 is configured to be arranged so as to cover the cup-side drainpipe 601 (drainage port) from below. The handle portion 442 is integrally provided with the lid portion 441 so as to be continuous with the lid portion 441. The liquid receiving portion 440 is configured to be rotatable about a predetermined position as a rotation axis by applying a force to the handle portion 442. In the liquid receiving portion 440, when a force is applied downward to the handle portion 442, the liquid receiving portion 440 is displaced upward to cover the cup-side drainpipe 601. In addition, in the liquid receiving portion 440, the handle portion 442 contacts the upper portion of the stopper 450. An upward force is applied to the handle portion 442, thereby displacing the liquid receiving portion 440 downward so that the liquid receiving portion 440 is removed from cup-side drainpipe 601. In this way, the stopper 450 contacts the handle portion 442 when moving the cup 21a to connect the cup-side drainpipe 601 and the connection pipe 302 of the drainpipe 300. As a result, the liquid receiving portion 440 is rotated, and the lid portion 441 attached to the cup-side drainpipe 601 is removed from the cup-side drainpipe 601.

Such operations will be described with reference to FIGS. 15A to 15F. FIG. 15A shows a state in which the cup 21a is stored and the cup-side drainpipe 601 and the connection pipe 302 of the drainpipe 300 are connected to each other. From this state, the cup 21a is pulled upward (see FIG. 15B) when, for example, cup replacement is to be performed.

Then, as shown in FIG. 15C, a downward force is applied to the handle portion 442 of the liquid receiving portion 440 before the cup 21a is pulled out toward the operator area to perform the cup replacement. As a result, the lid portion 441 is rotated upward to cover the cup-side drainpipe 601.

Then, after the replacement of the cup 21a is completed as shown in FIG. 15D, the cup 21a is moved downward to connect the cup-side drainpipe 601 and the connection pipe 302 of the drainpipe 300 as shown in FIG. 15E. In this case, as shown in FIG. 15E, the upper portion of the stopper 450 contacts the handle portion 442, whereby the liquid receiving portion 440 is rotated and the lid portion 441 attached to the cup-side drainpipe 601 is removed from the cup-side drainpipe 601. Then, by moving the cup 21a further downward as shown in FIG. 15F, the cup-side drainpipe 601, from which the lid portion 441 is removed, and the connection pipe 302 of the drainpipe 300 are connected to each other.

With such a configuration, the lid portion 441 is automatically removed from the cup-side drainpipe 601 by the stopper 450 when the cup 21a is moved downward. Thus, the cup-side drainpipe 601 and the connection pipe 302 of the drainpipe 300 may be easily and reliably connected to each other.

Next, various exemplary embodiments of the present disclosure will be described below in [E1] to [E14].

[E1] A substrate processing apparatus includes: a rotary holder configured to hold and rotate a substrate; a cup arranged so as to surround the substrate held by the rotary holder; a coating liquid nozzle configured to inject a coating liquid onto the substrate; a removal liquid nozzle configured to inject, onto the substrate, a removal liquid for removing a film from a peripheral portion of the substrate; a nozzle tracking camera attached to a nozzle arm that holds the coating liquid nozzle so as to track the coating liquid nozzle and configured to capture an image of the coating liquid nozzle; and a processing space camera configured to capture an image of a processing space above the rotary holder.

[E2] The substrate processing apparatus of [E1] above further includes: an exhaust duct connected to an exhaust port of the cup and connected to an exhaust source; and a nozzle moving shaft configured to guide a movement of the nozzle arm that holds the coating liquid nozzle, wherein an area existing on an operator side in a plan view is defined as a front area, and an area on existing on a side opposite the front area and where a transfer processing is performed is defined as a rear area, the exhaust duct is arranged on one area of the front area and the rear area, and the nozzle moving shaft is arranged on the other area of the front area and the rear area.

[E3] The substrate processing apparatus of [E1] or [E2] above further includes: slide rails configured to hold the cup and pull out the cup by extending in a predetermined direction, wherein the slide rails include a first rail configured to hold the cup and a second rail configured to hold the first rail, and the cup is pulled out by extending the second rail in the predetermined direction and further extending the first rail in the predetermined direction.

[E4] The substrate processing apparatus of any one of [E1] to [E3] above further includes: a coating liquid nozzle standby bus provided in a standby section of the coating liquid nozzle, wherein the nozzle tracking camera is configured to acquire information on a position of the coating liquid nozzle with respect to the coating liquid nozzle standby bus and configured to acquire information on a liquid behavior in the coating liquid nozzle.

[E5] The substrate processing apparatus of any one of [E1] to [E4] above further includes: a removal liquid nozzle standby bus provided in a standby section of the removal liquid nozzle; and a bus camera configured to capture an image of the removal liquid nozzle positioned on the removal liquid nozzle standby bus, wherein the bus camera is provided in a region of the removal liquid nozzle standby bus that does not face the cup.

[E6] In the substrate processing apparatus of [E5] above, the removal liquid nozzle standby bus is entirely or partially formed with a mirror surface.

[E7] In the substrate processing apparatus of [E5] above, the removal liquid nozzle standby bus has a black surface in an area other than a lighting window.

[E8] In the substrate processing apparatus of any one of [E1] to [E7] above, the nozzle tracking camera is configured to capture the image of the coating liquid nozzle to obtain information relating to centering of the coating liquid nozzle with respect to the rotary holder, and the processing space camera is configured to capture an image of the coating liquid nozzle at an angle different from an angle of the nozzle tracking camera to obtain the information relating to centering of the coating liquid nozzle with respect to the rotary holder.

[E9] The substrate processing apparatus of any one of [E1] to [E8] above further includes: a processing liquid nozzle attached to the nozzle arm together with the coating liquid nozzle and configured to inject a processing liquid that facilitates spreading of the coating liquid onto the substrate, wherein the nozzle tracking camera includes a liquid lens capable of focusing on both the coating liquid nozzle and the processing liquid nozzle that move integrally with each other.

[E10] The substrate processing apparatus of [E2] above further includes: a drainpipe connected to a drainage port of the cup, wherein the drainpipe is configured to have a lower height than the exhaust duct and is arranged on the other area of the front area and the rear area.

[E11] The substrate processing apparatus of [E10] above further includes: a liquid receiving portion including a lid portion configured to be arranged to cover the drainage port and a handle portion continuous with the lid portion; and a stopper configured to, when moving the cup to connect the drainage port and the drainpipe, contact the handle portion to rotate the liquid receiving portion and remove the lid portion attached to the drainage port from the drainage port.

[E12] The substrate processing apparatus of any one of [E5] to [E7] above further includes: an illuminator configured to irradiate light toward the removal liquid nozzle positioned on the removal liquid nozzle standby bus, wherein the illuminator is provided on a side opposite the bus camera so as to sandwich the removal liquid nozzle standby bus between the bus camera and the illuminator.

[E13] A substrate processing method executed by using a substrate processing apparatus that includes a rotary holder, a coating liquid nozzle, a nozzle tracking camera, and a processing space camera, includes: a first operation of capturing a first image of the coating liquid nozzle from a first direction by the nozzle tracking camera; a second operation of capturing a second image of the coating liquid nozzle from a second direction different from the first direction by the processing space camera; and a third operation of adjusting centering of the coating liquid nozzle with respect to the rotary holder based on a capturing result obtained by the nozzle tracking camera and a capturing result obtained by the processing space camera.

[E14] A non-transitory computer-readable storage medium storing a program that causes the substrate processing apparatus to execute the substrate processing method of [E13] above.

According to the present disclosure in some embodiments, it is possible to provide a substrate processing apparatus which is suitable for coating a coating liquid on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a rotary holder configured to hold and rotate a substrate;
a cup arranged so as to surround the substrate held by the rotary holder;
a coating liquid nozzle configured to inject a coating liquid onto the substrate;
a removal liquid nozzle configured to inject, onto the substrate, a removal liquid for removing a film from a peripheral portion of the substrate;
a nozzle tracking camera attached to a nozzle arm that holds the coating liquid nozzle so as to track the coating liquid nozzle and configured to capture an image of the coating liquid nozzle; and
a processing space camera configured to capture an image of a processing space above the rotary holder.

2. The substrate processing apparatus of claim 1, further comprising:
an exhaust duct connected to an exhaust port of the cup and connected to an exhaust source; and
a nozzle moving shaft configured to guide a movement of the nozzle arm that holds the coating liquid nozzle,
wherein an area existing on an operator side in a plan view is defined as a front area, and an area existing on a side opposite the front area and where a transfer processing is performed is defined as a rear area, the exhaust duct is arranged on one area of the front area and the rear area, and the nozzle moving shaft is arranged on the other area of the front area and the rear area.

3. The substrate processing apparatus of claim 1, further comprising:
slide rails configured to hold the cup and pull out the cup by extending in a predetermined direction,
wherein the slide rails include a first rail configured to hold the cup and a second rail configured to hold the first rail, and
wherein the cup is pulled out by extending the second rail in the predetermined direction and further extending the first rail in the predetermined direction.

4. The substrate processing apparatus of claim 1, further comprising:
a coating liquid nozzle standby bus provided in a standby section of the coating liquid nozzle,
wherein the nozzle tracking camera is configured to acquire information on a position of the coating liquid nozzle with respect to the coating liquid nozzle standby bus and configured to acquire information on a liquid behavior in the coating liquid nozzle.

5. The substrate processing apparatus of claim 1, further comprising:
a removal liquid nozzle standby bus provided in a standby section of the removal liquid nozzle; and
a bus camera configured to capture an image of the removal liquid nozzle positioned on the removal liquid nozzle standby bus,
wherein the bus camera is provided in a region of the removal liquid nozzle standby bus that does not face the cup.

6. The substrate processing apparatus of claim 5, wherein the removal liquid nozzle standby bus is entirely or partially formed with a mirror surface.

7. The substrate processing apparatus of claim 5, wherein the removal liquid nozzle standby bus has a black surface in an area other than a lighting window.

8. The substrate processing apparatus of claim 1, wherein the nozzle tracking camera is configured to capture the image of the coating liquid nozzle to obtain information relating to centering of the coating liquid nozzle with respect to the rotary holder, and
wherein the processing space camera is configured to capture an image of the coating liquid nozzle at an angle different from an angle of the nozzle tracking camera to obtain the information relating to centering of the coating liquid nozzle with respect to the rotary holder.

9. The substrate processing apparatus of claim 1, further comprising:
a processing liquid nozzle attached to the nozzle arm together with the coating liquid nozzle and configured to inject a processing liquid that facilitates spreading of the coating liquid onto the substrate,
wherein the nozzle tracking camera includes a liquid lens capable of focusing on both the coating liquid nozzle and the processing liquid nozzle that move integrally with each other.

10. The substrate processing apparatus of claim 2, further comprising:
a drainpipe connected to a drainage port of the cup,
wherein the drainpipe is configured to have a lower height than the exhaust duct and is arranged on the other area of the front area and the rear area.

11. The substrate processing apparatus of claim 10, further comprising:
a liquid receiving portion including a lid portion configured to be arranged to cover the drainage port and a handle portion continuous with the lid portion; and
a stopper configured to, when moving the cup to connect the drainage port and the drainpipe, contact the handle portion to rotate the liquid receiving portion and remove the lid portion attached to the drainage port from the drainage port.

12. The substrate processing apparatus of claim 5, further comprising:
an illuminator configured to irradiate light toward the removal liquid nozzle positioned on the removal liquid nozzle standby bus,
wherein the illuminator is provided on a side opposite the bus camera so as to sandwich the removal liquid nozzle standby bus between the bus camera and the illuminator.

13. A substrate processing method executed by using a substrate processing apparatus that includes a rotary holder configured to hold and rotate a substrate, a coating liquid nozzle configured to inject a coating liquid onto the substrate, a nozzle tracking camera attached to a nozzle arm that holds the coating liquid nozzle so as to track the coating liquid nozzle and configured to capture an image of the coating liquid nozzle, and a processing space camera configured to capture an image of a processing space above the rotary holder, the substrate processing method comprising:
a first operation of capturing a first image of the coating liquid nozzle from a first direction by the nozzle tracking camera;
a second operation of capturing a second image of the coating liquid nozzle from a second direction different from the first direction by the processing space camera; and
a third operation of adjusting centering of the coating liquid nozzle with respect to the rotary holder based on a capturing result obtained by the nozzle tracking camera and a capturing result obtained by the processing space camera.

14. A non-transitory computer-readable storage medium storing a program that causes the substrate processing apparatus to execute the substrate processing method of claim 13.
